(19) United States
(12) Patent Application Publication
(10) Pub. No.: US 2008/0191367 A1
(43) Pub. Date: Aug. 14, 2008

(54) SEMICONDUCTOR PACKAGE WIRE BONDING

(75) Inventor: Taehun Kim, Ichon-Si (KR)

Correspondence Address: KLARQUIST SPARKMAN, LLP, 121 SW SALMON STREET, SUITE 1600, PORTLAND, OR, 97204, US

(73) Assignee: STATS ChipPAC, Ltd.

(21) Appl. No.: 11/672,910

(22) Filed: Feb. 8, 2007

(51) Int. Cl. H01L 23/49; B23K 1/20; B23K 31/02

(52) U.S. Cl. 257/784; 228/203; 228/180.5; 228/170; 257/E23.024

(57) ABSTRACT

A stacked die semiconductor package comprises a die coupled to a substrate, the first die having a die bonding area, a bonding wire supporting layer affixed to a top surface of the first die, and a bonding wire bonded to the die bonding area and to a substrate bonding area on the substrate, the bonding wire fixably attached to the bonding wire supporting layer.

### TECHNICAL FIELD

The technical field relates generally to semiconductor packages and, more specifically, to wire bonding techniques.

### BACKGROUND

Semiconductor packages can be found in practically every electronic product manufactured today. As manufacturers strive to decrease the size while expanding the functionality of such products, the need for greater semiconductor package density and reliability increases. As such, wire bonding techniques play an ever-increasing role in the area of electronics manufacturing. Wire bonding is generally considered the most cost-effective and flexible interconnect technology, and is used to assemble the vast majority of semiconductor packages.

A wire bond is a welded electrical interconnection, usually from a semiconductor die to a non-common lead frame or substrate pad. Gold wire is usually used for interconnection techniques, though other wires such as aluminum and copper also have been used.

There are two main wire bonding techniques commonly used today: ball bonding and wedge bonding. Ball bonding is currently the most common method of wire bonding. Almost all modern ball bonding processes use a combination of heat, pressure, and ultrasonic energy to make a weld at each end of the wire. During this process, the end of the bond wire is converted to a ball shape by application of an electronic flame-off. The ball is then positioned just above the bond pad on a substrate or package and connected to the bond pad. An intermetallic bond is created by interdiffusion between the wire materials and the pad metallization.

Wedge bonding involves using ultrasonic energy and pressure to create a bond between the wire and the bond pad. Wedge bonding is generally a low-temperature process that uses frequencies between 20 and 60 kHz for standard applications and 120 kHz for fine pitch applications. This cold-welding process deforms the wire into a flat, elongated wedge shape. The most common method of wedge bonding is wedge-wedge bonding, where both the source bond and the destination bond are formed with wedge geometry.

Other wire bonding methods also can be used. For example, in ball-wedge bonding, the first bond (the source bond) takes a ball shape and the second bond (the destination bond) takes a wedge shape.

Demand for high-performance integrated circuit (IC) design may prompt an increase in the number of input/output (PO) connections, such as bond pads, for a given die. An increased number of I/O connections currently may be achieved by reducing bond pad size, thereby allowing a greater number of bond pads to be formed on a die. Decreased bond pad size, however, necessitates a reduced bonding wire diameter. Also, as packages become finer in structure, package thickness becomes thinner, resulting in increased wire length. Decreasing wire diameter, especially when coupled with increased wire length, presents multiple disadvantages, such as an increase in resistance and inductance in the wire and thus a decrease in IC performance quality.

Another disadvantage of decreasing wire diameter and/or increasing wire length is to exacerbate the effect of wire sweeping during molding. Wire sweeping generally refers to a situation involving a wire moving out of place. To counteract wire sweeping, wire length may be reduced, but reducing wire length increases manufacturing completely because, for example, bonding close to package walls is usually required, which can lead to mechanical interference.

Therefore, despite the advantages of the various developments in semiconductor packaging technology, there remains a need for increased semiconductor package density and reliability.

### SUMMARY

A semiconductor package can comprise a die coupled to a substrate, the die having multiple bonding areas such as bonding pads. A bonding wire supporting layer, such as a film or epoxy, for example, can be affixed to the top of the die. The bonding wire supporting layer can have a cut-out area to provide clearance for and access to the bonding areas on the die. Multiple bonding wires can be desirably attached to at least some of the bonding areas on the die and also to substrate bonding areas on the substrate. The bonding wires typically can be held in place proximate a first end by the bonding wire supporting layer. In some embodiments, the bonding wires can be held in place proximate a second end by a bond, such as a ball bond. In some embodiments, a bump can be located effectively to strengthen the physical connection of the bonding wire to the bonding area on the substrate. In some exemplary embodiments, multiple dies, each having its own bonding wire supporting layer having at least one appropriate cut-out area, can be stacked on top of each other.

In one exemplary embodiment, a method of making a semiconductor package can comprise providing an integrated circuit chip having a chip bonding area and coupling the integrated circuit chip to a substrate having a substrate bonding area. A bonding wire supporting layer can be provided and attached to the integrated circuit chip. A bonding wire can be attached to the chip bonding area at a first end or portion and to the substrate bonding area at the other end or portion, for example, by ball bonding. The bonding wire can be affixed to the bonding wire supporting layer. In some embodiments, multiple integrated circuit chips, each having its own bonding wire supporting layer, can be stacked on top of each other.

The foregoing and other objects, features, and advantages of the disclosed technologies will become more apparent from the following detailed description, which proceeds with reference to the accompanying figures.

### BRIEF DESCRIPTION OF THE FIGURES

FIG. 1 is a perspective view of an exemplary embodiment of a semiconductor package implementing the disclosed wire bonding technologies.

FIG. 2 is a perspective view of an exemplary die.

FIG. 3 is a perspective view of an exemplary bonding wire supporting layer cut to be compatible with the exemplary die of FIG. 2.

FIG. 4 is a perspective view of the exemplary bonding wire supporting layer of FIG. 3 prior to being mounted to the exemplary die of FIG. 2.

FIG. 5 is a perspective view of the exemplary bonding wire supporting layer of FIG. 4 attached to the exemplary die of FIG. 4.

FIG. 6 is a perspective view of exemplary bonding wires electrically coupled with the exemplary die of FIG. 5 and fixably attached to the bonding wire supporting layer of FIG. 5.

FIG. 7 is a perspective view of another exemplary bonding wire supporting layer attached to another exemplary die prior to being mounted to the exemplary bonding wire supporting layer of FIG. 6.

FIG. 8 is a perspective view of the two exemplary bonding wire supporting layers of FIG. 7 attached to each other with the exemplary bonding wires fixably attached to both layers.

FIG. 9 is a perspective view of a first embodiment of a bonding wire supporting layer.

FIG. 10 is a perspective view of a second embodiment of a bonding wire supporting layer.

FIG. 11 is a perspective view of a third embodiment of a bonding wire supporting layer.

FIG. 12 is a perspective view of a fourth embodiment of a bonding wire supporting layer.

FIG. 13 is a flowchart of an exemplary method for creating a semiconductor package according to the disclosed wire bonding technologies.

As used in this application and in the claims, the singular forms “a,” “an,” and “the” include the plural forms unless the context clearly dictates otherwise. Additionally, the term “includes” means “comprises.” Further, the term “coupled” generally means electrically, electromagnetically, and/or physically (e.g., mechanically or chemically) coupled or linked and does not exclude the presence of intermediate elements between the coupled items.

Although the operations of exemplary embodiments of the disclosed method may be described in a particular, sequential order for convenient presentation, it should be understood that disclosed embodiments can encompass an order of operations other than the particular, sequential order disclosed. For example, operations described sequentially may in some cases be rearranged or performed concurrently.

Moreover, for the sake of simplicity, the attached figures may not show the various ways (readily discernable, based on this disclosure, by one of ordinary skill in the art) in which the disclosed system, method, and apparatus can be used in combination with other systems, methods, and apparatuses. Additionally, the description sometimes uses terms such as “produce” and “provide” to describe the disclosed method. These terms are high-level abstractions of the actual operations that can be performed. The actual operations that correspond to these terms can vary depending on the particular implementation and are, based on this disclosure, readily discernible by one of ordinary skill in the art.

### Exemplary Embodiments of Semiconductor Packages Using Wire Bonding Technologies

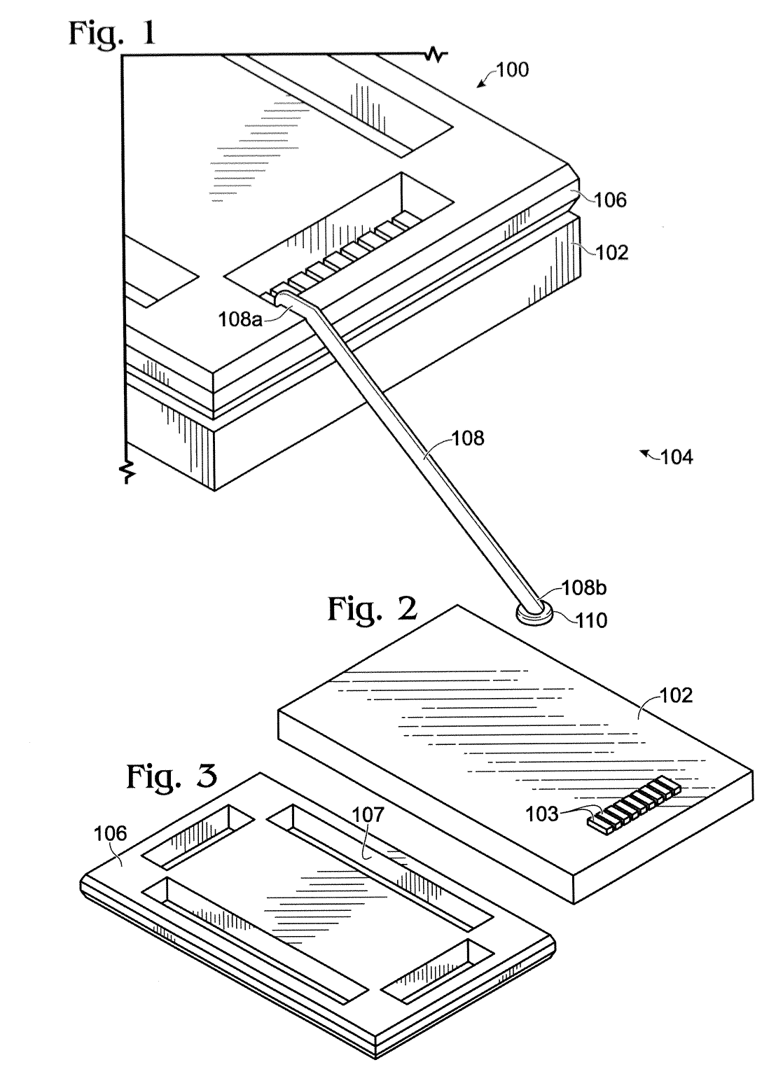

FIG. 1 is a perspective view of an exemplary embodiment of a semiconductor package 100 implementing the disclosed wire bonding technologies. In the example, a die 102 is mounted on a substrate 104. A person of ordinary skill in the art can appreciate that the die 102 can be coupled, for example, to the substrate 104 by an adhesive (not shown). In the example, a bonding wire supporting layer 106 is mounted on top of the die 102. A bonding wire 108 having a first end 108a and a second end 108b is coupled to a die bonding pad (not visible) on the die 102 and also to a bonding bump 110 on the substrate 104. The bonding wire 108 is fixably held in place by the bonding wire supporting layer 106. Holding the bonding wire 108 in place at the end 108a closest to the die 102 advantageously increases wire strength, even if there is increased wire tension, thereby decreasing the chances of wire sweeping or even wire breakage.

In other embodiments, a bonding bump may be omitted. A bonding bump may, however, advantageously increase the strength of holding bonding wire 108 in place at the end closest to the substrate 104, thereby further decreasing the chances of wire sweeping and wire breakage.

Various other advantages flow from the disclosed technologies such as the exemplary arrangement of FIG. 1. For example, the space needed between bonding wires can be significantly reduced, thereby allowing for denser wire bonding. In some embodiments, one half of the bonding wire thickness can be sufficient for avoiding wire shorts. Also, the ability to have increased wire tension can provide for relatively flat wires, thereby enabling easy and safe stacking of multiple chips.

FIG. 2 is a perspective view of the exemplary die 102 of FIG. 1. The die 102 has multiple die bonding pads 103. Bonding wires (not shown) may be coupled to the pads 103 using a wire bonding method such as ball bonding.

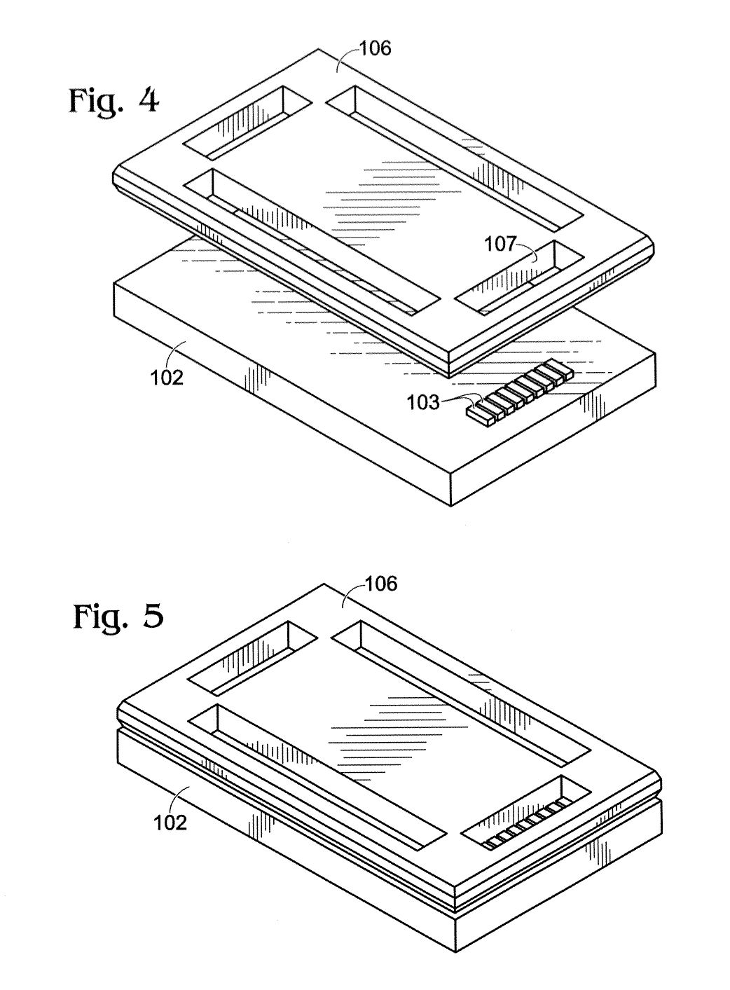

FIG. 3 is a perspective view of the exemplary bonding wire supporting layer 106 of FIG. 1 cut to be compatible with the exemplary die 102. In the exemplary embodiment illustrated in FIG. 3, the bonding wire supporting layer 106 has multiple rectangular-shaped cut-out areas 107 to accommodate the die bonding pads 103 of the die 102 when the bonding wire supporting layer 106 is attached to the die 102. A wire bonding supporting layer cutter (e.g., a typical film cutter) may be used to create the cut-out areas 107. One of ordinary skill in the art will understand that the shape(s) of the cut-out areas need not be rectangular and that there could be individual portions to accommodate each or groups of the die bonding pads 103.

FIG. 4 is a perspective view of the exemplary bonding wire supporting layer 106 prior to being mounted to the exemplary die 102. One of ordinary skill in the art will appreciate that the cut-out areas 107 provide clearance for the die bonding pads 103 on the die 102.

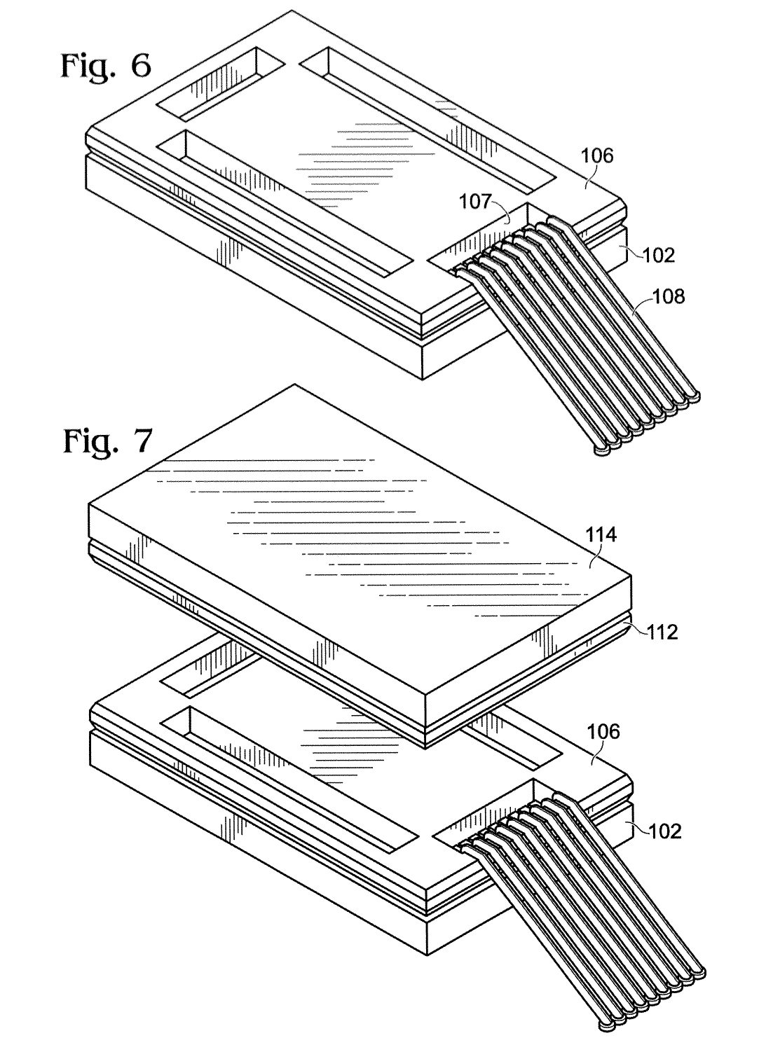

FIG. 5 is a perspective view of the exemplary bonding wire supporting layer 106 attached to the exemplary die 102. In some embodiments, the bonding wire supporting layer 106 is a film that can be attached to the die 102, for example, by using an adhesive (not shown). In other embodiments, the bonding wire supporting layer 106 is an epoxy.

FIG. 6 is a perspective view of exemplary bonding wires 108 electrically coupled with the exemplary die 102 and fixably attached to the bonding wire supporting layer 106. One of ordinary skill in the art will appreciate that depending on certain factors, such as the size and shape of the cut-out areas 107 in the wire bonding supporting layer 106, each wire 108 defines a bonding surface area, at least a portion of which can be actually bonded. In some embodiments, for example, a significant portion of each bonding wire 108 may be affixed to the bonding wire supporting layer 106 in order to maximize holding strength.

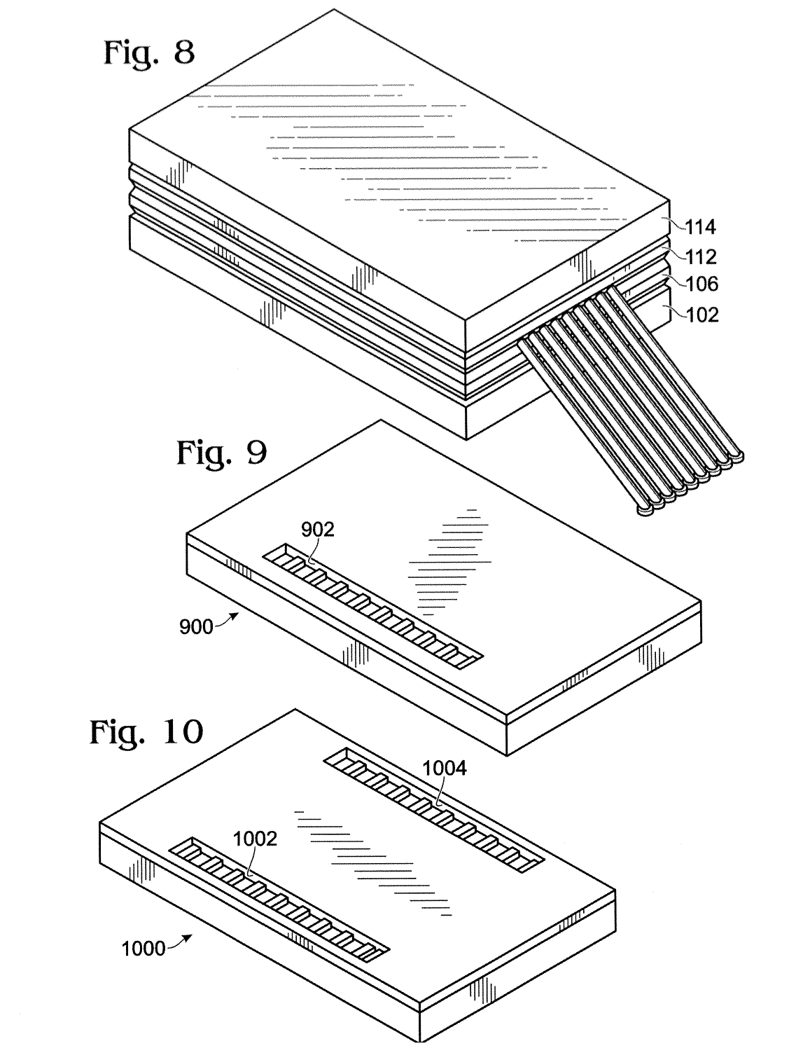

FIG. 7 is a perspective view of a second exemplary bonding wire supporting layer 112 effectively coupled to a second exemplary die 114 prior to being mounted to the exemplary bonding wire supporting layer 106. As discussed above, disclosed embodiments of wire bonding technologies facilitate safe stacking of multiple dies.

FIG. 8 is a perspective view of the two exemplary bonding wire supporting layers 106, 112 effectively coupled to each other. In some embodiments, the two bonding wire supporting layers 106, 112 may be affixed to each other by using an adhesive layer. In some embodiments, a layer 112 may have adhesion using wafer backside lamination (WBL). If the adhesion is not enough, the other layer 106 may also have adhesion.

In some embodiments, one or both of the bonding wire supporting layers 106, 112 are epoxies. In this example, the exemplary bonding wires 108 remain fixably attached to the bonding wire supporting layer 106. In some embodiments, the bonding wires 108 are fixably attached to both bonding wire supporting layers 106, 112. In some embodiments, the die 102 with bonding wire supporting layer 106 is placed on a heat block. Because of the generally high temperature of the heat block (e.g., 150 degrees Celsius) the bonding wire supporting layer 106 can turn into postage (e.g. between liquid and solid) such that the bonding wires 108 can sink to the edge surface of the bonding wire supporting layer 106. The second die 114 with bonding wire supporting layer 112 attached can be attached to the first die 102 with bonding wire supporting layer 106 using, for example, WBL, after which the bonding wires 108 are thus fixably attached to both of the bonding wire supporting layers 106, 112.

FIG. 9 is a perspective view of a first embodiment of a bonding wire supporting layer 900. In the example, the bonding wire supporting layer 900 has a single cut-out area 902 that is rectangular in shape.

FIG. 10 is a perspective view of a second embodiment of a bonding wire supporting layer 1000. In this exemplary embodiment, the bonding wire supporting layer 1000 has two cut-out areas 1002, 1004 that are both rectangular in shape and that are substantially similar in size. One of ordinary skill in the art will recognize that (1) the cut-out areas 1002, 1004 need not be rectangular, and (2) the cut-out areas 1002, 1004 can be of substantially different sizes, or both. This arrangement can be particularly useful when mounted on dies that have two rectangular rows of die bonding pads to which bonding wires are to be attached.

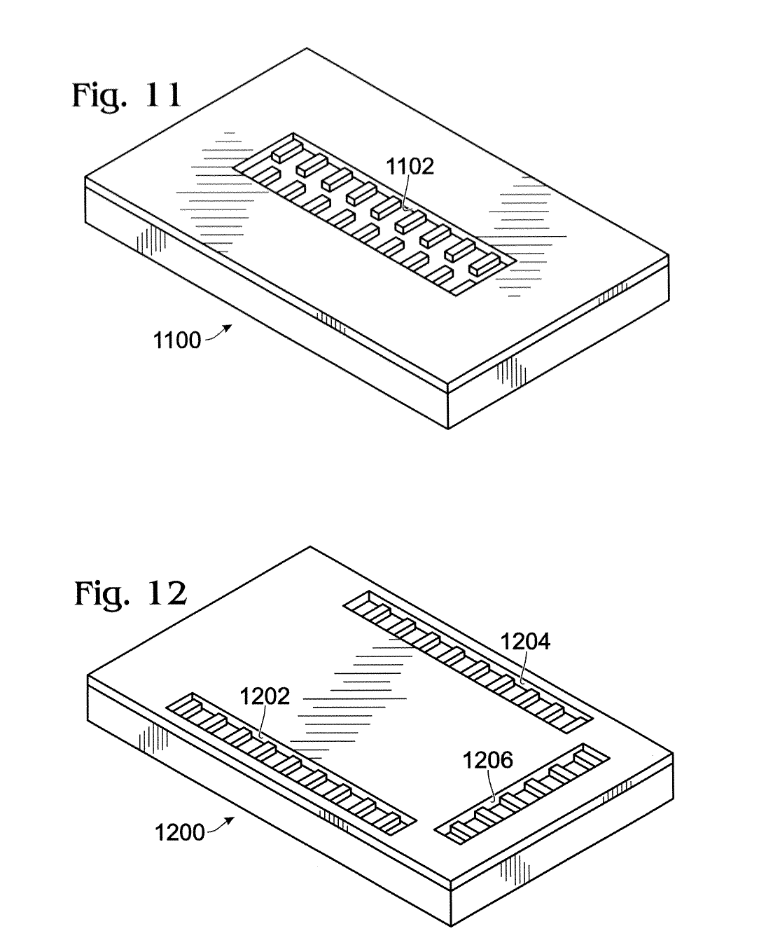

FIG. 11 is a perspective view of a third embodiment of a bonding wire supporting layer 100. In the example, the bonding wire supporting layer 1100 has a single cut-out area 1102 that is rectangular in shape and significantly larger than any of the exemplary cut-out areas of FIGS. 9 and 11. This arrangement can be particularly useful when mounted on dies that have multiple die bonding areas and/or components in the central area of the die.

FIG. 12 is a perspective view of a fourth embodiment of a bonding wire supporting layer 1200. In the example, the bonding wire supporting layer 1200 has two cut-out areas 1202, 1204 that are both rectangular in shape and that are substantially similar in size. The bonding wire supporting layer 1200 has a third cut-out area 1206 that is also rectangular in shape but which is smaller in size than either of the other two cut-out areas 1202, 1204. One or ordinary skill in the art will appreciate that the number of, positions of, and shapes of cut-out areas (e.g., 1202, 1204, 1206) are unlimited.

### Exemplary Embodiments of a Method of Creating a Semiconductor Package using Wire Bonding Technologies

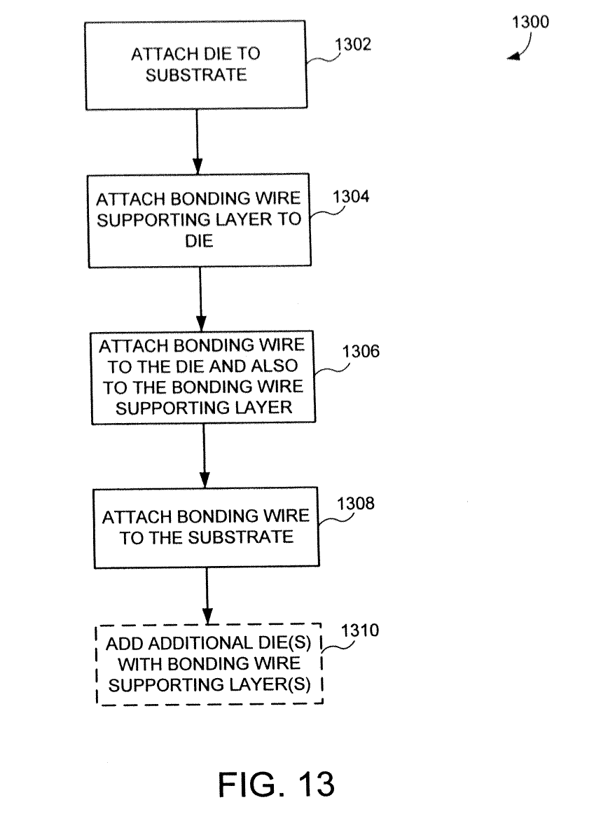

FIG. 13 is a flowchart of an exemplary method 1300 for creating a semiconductor package according to the disclosed wire bonding technologies. A die can be coupled to the top surface of a substrate (step 1302). A bonding wire supporting layer can be applied to the top surface of the first die (step 1304). In some embodiments, certain areas of the bonding wire supporting layer are cut out. In other embodiments, the bonding wire supporting layer is pre-cut. At least one bonding wire is electrically coupled to the die, such as by way of a die bonding pad, and is also fixably attached to the bonding wire supporting layer (step 1306). The bonding wire then can be attached to the substrate by way of, for example, a bonding pad (step 1308). In some embodiments, a bond ball can be used to strengthen the physical connection between the bonding wire and the bonding area on the substrate. In some embodiments, an additional die having its own bonding wire supporting layer can be applied to the top surface of the bonding wire supporting layer (step 1310). In some embodiments, multiple dies, each having its own bonding wire supporting layer attached, can be stacked on top of each other as well as on top of the original bonding wire supporting layer mounted on top of the original die.

The exemplary embodiments of the disclosed system, method, and apparatus should not be construed as limiting in any way. Instead, the present disclosure is directed toward all novel and nonobvious features, aspects, and equivalents of the various disclosed embodiments, alone and in various combinations and sub-combinations with one another. The disclosed technology is not limited to any specific aspect, feature, or combination thereof, nor do the disclosed system, method, and apparatus require that any one or more specific advantages be present or problems be solved. The scope of the invention is defined by the following claims. We therefore claim as our invention all that comes within the scope and spirit of these claims.

1. A semiconductor package, comprising:
a substrate having at least one bonding area;
a first die coupled to a top surface of the substrate, wherein the first die has at least one die bonding area;
a first bonding wire supporting layer affixed on a top surface of the first die; and
at least one bonding wire bonded to the at least one bonding area and the at least one die bonding area, wherein the at least one bonding wire is fixably attached to the first bonding wire supporting layer.

2. The semiconductor package of claim 1, wherein the first bonding wire supporting layer comprises a film.

3. The semiconductor package of claim 1, wherein the first bonding wire supporting layer comprises an epoxy.

4. The semiconductor package of claim 1, wherein the at least one bonding wire is a gold wire.

5. The semiconductor package of claim 1, further comprising a bump on the at least one bonding area, wherein the bump fixably couples the at least one bonding wire to the at least one bonding area.

6. The semiconductor package of claim 1, wherein the bonding wire has a tension between the first bonding wire supporting layer and the at least one bonding area.

7. The semiconductor package of claim 1, further comprising a second bonding wire supporting layer affixed on a top surface of the first bonding wire supporting layer.

8. The semiconductor package of claim 7, further comprising a second die affixed on a top surface of the second bonding wire supporting layer.

9. The semiconductor package of claim 7, wherein the second bonding wire supporting layer comprises a film.

10. The semiconductor package of claim 7, wherein the second bonding wire supporting layer comprises an epoxy.

11. A method for making a semiconductor package, comprising:
providing a first integrated circuit chip having a top surface and at least one chip bonding area;
coupling the first integrated circuit chip to a top surface of a substrate having at least one substrate bonding area;
providing a first bonding wire supporting layer;
coupling the first bonding wire supporting layer to the top surface of the first integrated circuit chip;
providing a bonding wire;
coupling the bonding wire to the at least one chip bonding area on the first integrated circuit chip;
coupling the bonding wire to the at least one substrate bonding area on the substrate; and
affixing the bonding wire to the bonding wire supporting layer.

12. The method of claim 11, further comprising:
providing a second integrated circuit chip having a bottom surface and at least one chip bonding area;
providing a second bonding wire supporting layer having a top surface and a bottom surface;
coupling the bottom surface of the second integrated circuit chip to the top surface of the second bonding wire supporting layer; and
coupling the bottom surface of the second bonding wire supporting layer to the top surface of the first bonding wire supporting layer.

13. The method of claim 1 further comprising:
identifying an area on the first bonding wire supporting layer to be cut out to provide clearance for the at least one chip bonding area on the first integrated circuit chip; and
cutting out the identified area on the first bonding wire supporting layer.

14. The method of claim 12, further comprising:
identifying an area on the first bonding wire supporting layer to be cut out to provide clearance for the at least one chip bonding area on the first integrated circuit chip;
cutting out the identified area on the first bonding wire supporting layer;
identifying an area on the second bonding wire supporting layer to be cut out to provide clearance for the at least one chip bonding area on the second integrated circuit chip; and
cutting out the identified area on the second bonding wire supporting layer.

15. A semiconductor package made according to the method of claim 11.

16. The method of claim 15, further comprising including the semiconductor package in a computer, personal digital assistant, digital camera, or cellular telephone.

17. A stacked die semiconductor package, comprising:
a substrate;
a first die coupled to a top surface of the substrate;
a first bonding wire film affixed on top of the first die; and
a plurality of bonding wires electrically coupled to the first die and the substrate and also fixably attached to the first bonding wire film.

18. The semiconductor package of claim 17, further comprising:
a second die; and
a second bonding wire film affixed underneath the second die and on top of the first bonding wire film.

19. The semiconductor package of claim 17, further comprising:
a second die; and
a bonding wire epoxy affixed underneath the second die and on top of the first bonding wire film.

20. The semiconductor package of claim 18, further comprising:
a third die; and
a third bonding wire film affixed underneath the third die and on top of the second bonding wire film.
